(19) United States
(12) Patent Application Publication
(10) Pub. No.: US 2019/0004134 A1
(43) Pub. Date: Jan. 3, 2019

(54) MAGNETIC RESONANCE IMAGING APPARATUS AND MAGNETIC RESONANCE IMAGING METHOD

(71) Applicant: Canon Medical Systems Corporation, Otawara-shi (JP)

(72) Inventors: Yuko HARA, Delafield, WI (US); Kanako Saito, Ota (JP); Taichiro Shiodera, Ota (JP); Tomoyuki Takeguchi, Kawasaki (JP); Takashi Shigeta, Nasushiobara (JP); Masao Yui, Otawara (JP); Hiroshi Kusahara, Utsunomiya (JP); Yuki Takai, Nasushiobara (JP); Yoshimori Kasai, Nasushiobara (JP)

(73) Assignee: Canon Medical Systems Corporation, Otawara-shi (JP)

(21) Appl. No.: 16/022,089

(22) Filed: Jun. 28, 2018

(30) Foreign Application Priority Data
Jun. 30, 2017 (JP) 2017-129740

(51) Int. Cl. G01R 33/48; G01R 33/54; G01R 33/56

(52) U.S. Cl. CPC G01R 33/4818; G01R 33/5602; G01R 33/543

(57) ABSTRACT

A magnetic resonance imaging apparatus according to an embodiment includes sequence controlling circuitry and processing circuitry. The sequence controlling circuitry acquires first k-space data in units of a plurality of segments while arranging the plurality of segments to overlap one another in a read-out direction, the first k-space being divided into the plurality of segments in the read-out direction. The processing circuitry calculates a weighting coefficient on a basis of information about a gradient magnetic field related to the acquisition and generates second k-space data on a basis of the plurality of segments in the first k-space data and the weighting coefficient.

### CROSS-REFERENCE TO RELATED APPLICATIONS

This application is based upon and claims the benefit of priority from Japanese Patent Application No. 2017-129740, filed on Jun. 30, 2017; the entire contents of which are incorporated herein by reference.

### FIELD

Embodiments described herein relate generally to a magnetic resonance imaging apparatus and a magnetic resonance imaging method.

### BACKGROUND

As one of magnetic resonance imaging methods, a Multi Shot Echo Planar Imaging (EPI) scheme is known by which k-space data is acquired while using a plurality of RF pulses. In comparison to Single Shot Echo Planar Imaging (SSEPI) schemes by which data in the entire k-space is acquired while using a single RF pulse, the Multi Shot EPI scheme is able to better enhance the spatial resolution of medical images. According to the Multi Shot EPI scheme, the k-space is divided into a plurality of segments and the data acquiring process is performed multiple times, so as to acquire pieces of k-space data corresponding to the segments separately from one another. After that, final k-space data is generated by combining together the plurality of segments in the k-space data that were acquired.

As a method of the Multi Shot EPI scheme, a Readout Segmented EPI (RSEPI) method is known. According to the RSEPI method, usually, the k-space is divided into a plurality of segments in the read-out direction, so as to acquire data in each of the segments. After that, final k-space data is generated by combining together the plurality of segments in the k-space data that were acquired.

In some situations, however, the final k-spaced data generated from the combining process in this manner may have degraded image quality in certain positions in the k-space.

### BRIEF DESCRIPTION OF THE DRAWINGS

FIG. 1 is a diagram illustrating a magnetic resonance imaging apparatus according to an embodiment;

FIG. 2 is a drawing illustrating a data acquisition performed by the magnetic resonance imaging apparatus according to the embodiment;

FIG. 3 is a drawing for explaining a data processing process performed by a magnetic resonance imaging apparatus according to a conventional technique;

FIG. 4 is a drawing for explaining a background of the magnetic resonance imaging apparatus according to the embodiment;

FIG. 5 is a flowchart for explaining a procedure in a process performed by the magnetic resonance imaging apparatus according to the embodiment;

FIG. 6 is a drawing for explaining a weighting coefficient determining process performed by the magnetic resonance imaging apparatus according to a first embodiment;

FIG. 7 is a drawing for explaining a weighting process performed by the magnetic resonance imaging apparatus according to the first embodiment;

FIG. 8 is a drawing for explaining a weighting coefficient calculating process performed by a magnetic resonance imaging apparatus according to a second embodiment; and

FIG. 9 is a drawing for explaining another weighting coefficient calculating process performed by the magnetic resonance imaging apparatus according to the second embodiment.

### DETAILED DESCRIPTION

A magnetic resonance imaging apparatus according to an embodiment includes sequence controlling circuitry and processing circuitry. The sequence controlling circuitry acquires first k-space data in units of a plurality of segments while arranging the plurality of segments to overlap one another in a read-out direction, the first k-space being divided into the plurality of segments in the read-out direction. The processing circuitry calculates a weighting coefficient on a basis of information about a gradient magnetic field related to the acquisition and generates second k-space data on a basis of the plurality of segments in the first k-space data and the weighting coefficient.

Exemplary embodiments of the magnetic resonance imaging apparatus will be explained in detail below, with reference to the accompanying drawings.

### First Embodiment

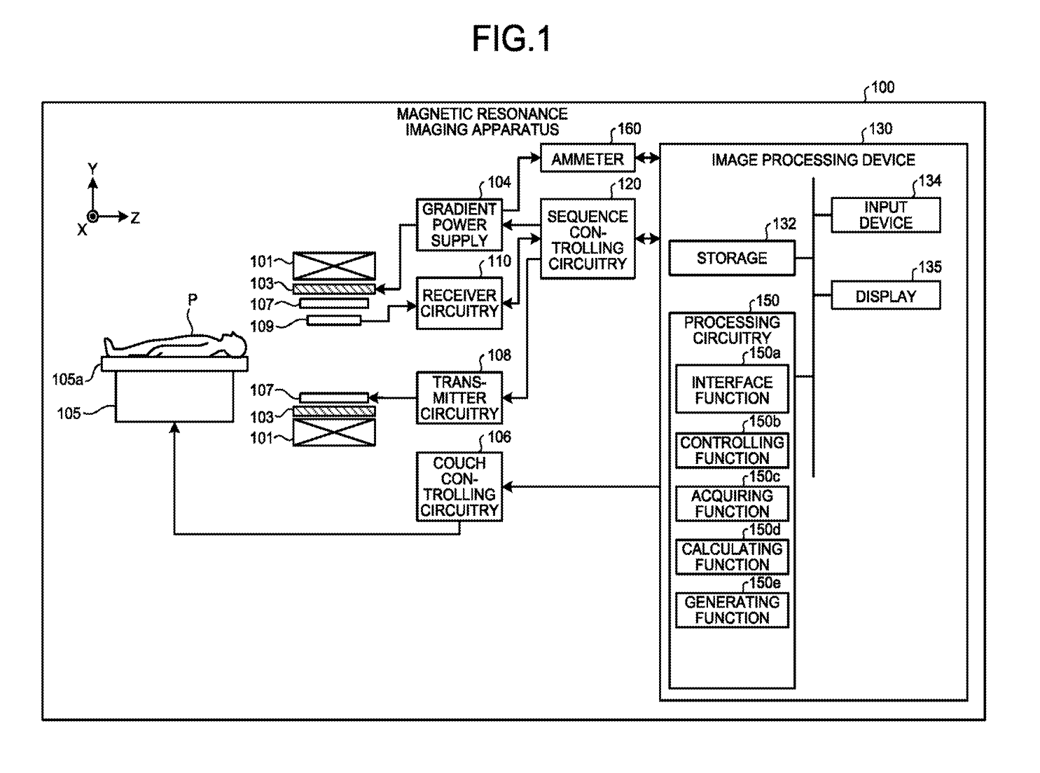

FIG. 1 is a block diagram illustrating a magnetic resonance imaging apparatus 100 according to an embodiment. As illustrated in FIG. 1, the magnetic resonance imaging apparatus 100 includes a static magnetic field magnet 101, a gradient coil 103, a gradient power source 104, a couch 105, couch controlling circuitry 106, a transmitter coil 107, transmitter circuitry 108, a receiver coil 109, receiver circuitry 110, sequence controlling circuitry 120, and an image processing device 130. Further, the magnetic resonance imaging apparatus 100 may include an ammeter 160. The magnetic resonance imaging apparatus 100 does not include an examined subject (hereinafter “patient”; represented by a human body, for example) P. Further, the configuration illustrated in FIG. 1 is merely an example. For instance, any of the functional units included in the sequence controlling circuitry 120 and the image processing device 130 may be integrated together or separated as appropriate.

The static magnetic field magnet 101 is a magnet formed to have a hollow and substantially circular cylindrical shape and configured to generate a static magnetic field in the space on the inside thereof. For example, the static magnetic field magnet 101 may be a superconductive magnet or the like and is configured to cause magnetic excitation by receiving a supply of an electric current from a static magnetic field power source (not illustrated). The static magnetic field power source is configured to supply the electric current to the static magnetic field magnet 101.

In place of the static magnetic field magnet 101, a permanent magnet may be used as the magnet. In that situation, the magnetic resonance imaging apparatus 100 does not necessarily have to include a static magnetic field power source. Further, the static magnetic field power source may be provided separately from the magnetic resonance imaging apparatus 100.

The gradient coil 103 is a coil formed to have a hollow and substantially circular cylindrical shape and is disposed on the inside of the static magnetic field magnet 101. The gradient coil 103 is structured by combining together three coils corresponding to X-, Y-, and Z-axes that are orthogonal to one another. By individually receiving a supply of an electric current from the gradient power source 104, these three coils are configured to generate gradient magnetic fields of which the magnetic field intensities change along the X-, Y-, and Z-axes respectively. The gradient magnetic fields generated along the X-, Y-, and Z-axes by the gradient coil 103 are, for example, a slice gradient magnetic field Gz, a phase-encoding gradient magnetic field Gy, and a read-out gradient magnetic field Gx (the gradient magnetic field Gx in the read-out direction). The gradient power source 104 is configured to supply the electric currents to the gradient coil 103.

During a data acquisition, the magnitude of the gradient magnetic field Gx in the read-out direction and a position Kx in the k-space in the x-direction in which the data is acquired are in a correspondence relationship expressed by Expression (1) presented below.

$${K}_{x} = \frac{1}{2 π} γ {L}_{x} {\int }_{{T}_{echo}}^{T} {G}_{x} dt \qquad ( 1 )$$

In Expression (1), Lx denotes a Field Of View (FOV) in the x-axis direction, γ denotes a gyromagnetic ratio, Techo denotes a time at an echo center, and T denotes a sampling time.

As understood from this expression, there is a correspondence relationship between the integrated value of the magnitudes of the gradient magnetic field Gx in the read-out direction to be applied and the positions in the k-space in each of which the data is acquired.

Positions in the k-space in actuality exhibit only integer values incrementing at regular intervals. For this reason, a sampling process is performed so that Kx exhibits integer values during the data acquisition. Normally, it is assumed that the gradient magnetic field Gx in the read-out direction is constant; however, when the gradient magnetic field Gx in the read-out direction is not constant (e.g., when a sampling process is performed during a rising time period of the gradient magnetic field), the position Kx in the k-space does not exhibit an integer value. In that situation, an interpolating process is performed so that pieces of data obtained during the acquisition are arranged at regular intervals in the k-space.

The couch 105 includes a couchtop 105a on which the patient P is placed. Under control of the couch controlling circuitry 106, the couchtop 105a is inserted to the inside of a hollow space (an image taking opening) of the gradient coil 103, while the patient P is placed thereon. Usually, the couch 105 is installed in such a manner that the longitudinal direction thereof extends parallel to the central axis of the static magnetic field magnet 101. Under control of the image processing device 130, the couch controlling circuitry 106 is configured to move the couchtop 105a in longitudinal directions and up-and-down directions by driving the couch 105.

The transmitter coil 107 is disposed on the inside of the gradient coil 103 and is configured to generate a radio frequency magnetic field by receiving a supply of a Radio Frequency (RF) pulse from the transmitter circuitry 108. The transmitter circuitry 108 is configured to supply the transmitter coil 107 with the RF pulse corresponding to a Larmor frequency determined by the type of the targeted atom and intensities of magnetic fields.

The receiver coil 109 is disposed on the inside of the gradient coil 103 and is configured to receive magnetic resonance signals emitted from the patient P due to an influence of the radio frequency magnetic field. When having received the magnetic resonance signals, the receiver coil 109 outputs the received magnetic resonance signals to the receiver circuitry 110.

The transmitter coil 107 and the receiver coil 109 described above are merely examples. One or more coils may be configured by selecting one or combining two or more from among the following: a coil having only a transmitting function; a coil having only a receiving function; and a coil having transmitting and receiving functions.

The receiver circuitry 110 is configured to detect the magnetic resonance signals output from the receiver coil 109 and to generate magnetic resonance data on the basis of the detected magnetic resonance signals. More specifically, the receiver circuitry 110 generates the magnetic resonance data by performing a digital conversion on the magnetic resonance signals output from the receiver coil 109. Further, the receiver circuitry 110 transmits the generated magnetic resonance data to the sequence controlling circuitry 120. The receiver circuitry 110 may be provided on the side of a gantry device where the static magnetic field magnet 101, the gradient coil 103, and the like are provided.

The sequence controlling circuitry 120 is configured to perform an image taking process on the patient P by driving the gradient power source 104, the transmitter circuitry 108, and the receiver circuitry 110 on the basis of sequence information transmitted thereto from the image processing device 130. In this situation, the sequence information is information defining a procedure for performing the image taking process. The sequence information defines: the intensity of the electric current to be supplied from the gradient power source 104 to the gradient coil 103 and the timing with which the electric current is to be supplied; the intensity of the RF pulse to be supplied from the transmitter circuitry 108 to the transmitter coil 107 and the timing with which the RF pulse is to be applied; the timing with which the magnetic resonance signals are to be detected by the receiver circuitry 110, and the like. For example, the sequence controlling circuitry 120 may be an integrated circuit such as an Application Specific Integrated Circuit (ASIC), a Field Programmable Gate Array (FPGA) or the like or an electronic circuit such as a Central Processing Unit (CPU), a Micro Processing Unit (MPU), or the like.

When having received the magnetic resonance data from the receiver circuitry 110 as a result of performing the image taking process on the patient P by driving the gradient power source 104, the transmitter circuitry 108, and the receiver circuitry 110, the sequence controlling circuitry 120 is configured to transfer the received magnetic resonance data to the image processing device 130.

In an embodiment, for example, the sequence controlling circuitry 120 performs a data acquisition by using a high-speed imaging method such as an Echo Planar Imaging (EPI) method, for example. According to the EPI method, data is acquired at a high speed in a continuous manner, by inverting the orientation of the gradient magnetic field Gx in the read-out direction during the data acquisition time period, with respect to the magnetic excitation caused by an RF pulse at a time. In particular, in the present embodiment, the sequence controlling circuitry 120 performs the data acquisition by implementing the Multi Shot Echo Planar Imaging (EPI) scheme by which k-space data is acquired while using a plurality of RF pulses. In comparison to Single Shot Echo Planar Imaging (SSEPI) schemes by which the data in the entire k-space is acquired while using a single RF pulse, the Multi Shot EPI scheme has an advantageous characteristic where it is possible to enhance spatial resolution of medical images, which is a final output, because the k-space is acquired by using the plurality of RF pulses.

By using the Multi Shot EPI scheme, the sequence controlling circuitry 120 acquires the k-space data in the process performed multiple times separately, by using the plurality of RF pulses. In other words, the sequence controlling circuitry 120 is configured to acquire first k-space data in units of a plurality of segments. After that, by employing a generating function 150e, the processing circuitry 150 (explained later) generates second k-space data on the basis of the plurality of segments in the first k-space data acquired by the sequence controlling circuitry 120 and further generates a proton distribution image (r-space data), which is an image to be output, on the basis of the generated second k-space data.

As a method of the Multi Shot EPI scheme, the Readout Segmented EPI (RSEPI) method is known by which data is acquired by dividing the k-space into segments in the read-out direction. According to the RSEPI method, the sequence controlling circuitry 120 divides the k-space into a number of segments in the read-out direction and acquires the data in each of the segments.

More specifically, with respect to each of the segments, the sequence controlling circuitry 120 applies an offset to positions in the k-space by applying a gradient magnetic field for a certain period of time before the sampling process. It is possible to express a position Kₓ in the k-space in the x-direction in which data is acquired by the sequence controlling circuitry 120, by using Expression (2) presented below, where an offset for an m'th segment is expressed as K′(m).

$${K}_{x} = \frac{1}{2 π} γ {L}_{x} {\int }_{{T}_{echo}}^{T} {G}_{x} dt + {K}^{′} ( m ) \qquad ( 2 )$$

In Expression (2), Lx denotes the FOV in the x-axis direction, γ denotes a gyromagnetic ratio, Techo denotes a time at an echo center for the m'th segment, and T denotes a sampling time.

The sequence controlling circuitry 120 acquires the first k-space data in such a manner that segments that are normally positioned adjacent to each other overlap each other in the k-space. Subsequently, by employing the generating function 150e, the processing circuitry 150 (explained later) generates the second k-space data by combining together the segments in the first k-space data.

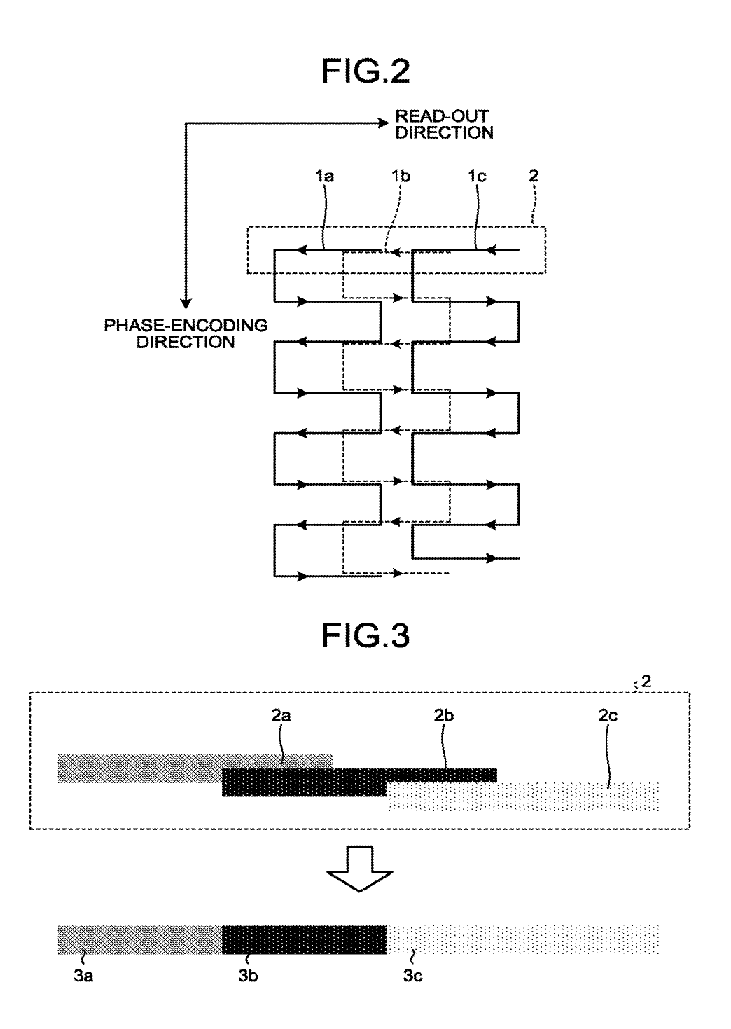

FIG. 2 illustrates an example of the acquisition according to the RSEPI method. FIG. 2 is a drawing illustrating a data acquisition performed by the magnetic resonance imaging apparatus according to the present embodiment. The horizontal axis in FIG. 2 expresses the read-out direction (kₓ) in the k-space, whereas the vertical axis in FIG. 2 expresses the phase-encoding direction (k_{y}) in the k-space.

Each of the trajectories 1a, 1b, and 1c in the k-space represents a trajectory of acquisition in the k-space during the data acquisition, with respect to one RF pulse. For example, by applying a first RF pulse, the sequence controlling circuitry 120 acquires data in the positions in the k-space represented by the trajectory 1a, during the data acquisition. Further, by applying a second RF pulse, the sequence controlling circuitry 120 acquires data in the positions in the k-space represented by the trajectory 1b, during the data acquisition. In this situation, for the purpose of enhancing redundancy of the data and increasing reliability of the data, the sequence controlling circuitry 120 acquires the data in such a manner that the trajectory 1a and the trajectory 1b form the trajectory 1b by overlapping each other in the k-space. In other words, the sequence controlling circuitry 120 performs the two acquisitions in such a manner that the data acquisition related to the first RF pulse and the data acquisition related to the second RF pulse overlap each other in the read-out direction. In this situation, the overlap in the read-out direction is, for example, an overlap by approximately 50%. Subsequently, the sequence controlling circuitry 120 applies a third RF pulse and acquires data in the positions in the k-space represented by the trajectory 1c during the data acquisition. In this situation, the sequence controlling circuitry 120 performs the data acquisitions in such a manner that the trajectory 1b and the trajectory 1c form the trajectory 1c by overlapping each other in the k-space. In this manner, the sequence controlling circuitry 120 acquires the first k-space data in units of the plurality of segments, while arranging the segments to overlap one another in the read-out direction.

In this regard, during the data acquisitions, the correspondence relationship expressed in Expression (1) above is satisfied between the magnitude of the gradient magnetic field Gₓ in the read-out direction and the position Kₓ in the k-space in the x-direction in which the data is acquired. Accordingly, in the time period of the data acquisition, by applying the gradient magnetic field Gₓ in the read-out direction that makes the integrated value of the magnitudes of the gradient magnetic field Gₓ in the read-out direction equal to a predetermined value corresponding to Kₓ, the sequence controlling circuitry 120 is able to acquire the data corresponding to the predetermined position in the k-space. In addition, a correspondence relationship similar to the one in Expression (1) is also satisfied between the gradient magnetic field G_{y} and K_{y} in the phase-encoding direction. Accordingly, by applying a blip pulse or the like, for example, the sequence controlling circuitry 120 is able to control the positions in the phase-encoding direction in which data is acquired. Further, as understood from Expression (1), by inverting the sign of the gradient magnetic field Gₓ in the read-out direction to be applied, the sequence controlling circuitry 120 is able to control the direction in the k-space in which the data is acquired.

The pulse sequence executed in the present embodiment is not limited to pulse sequences in the EPI scheme described above. The sequence controlling circuitry 120 may perform a process similar to that in the embodiment by using any other sequence by which the first k-space data is acquired in units of a plurality of segments, while arranging the segments to overlap one another in the read-out direction.

Returning to the description of FIG. 1, the ammeter 160 is an ammeter used for measuring the electric current flowing in the gradient power source 104. The ammeter 160 is connected to the gradient power source 104 and is configured to obtain a current value and to transmit the obtained current value to the image processing device 130.

The image processing device 130 is configured to exercise overall control of the magnetic resonance imaging apparatus 100 and to generate images, and the like. The image processing device 130 includes storage 132, an input device 134, a display 135, and processing circuitry 150. The processing circuitry 150 includes an interface function 150a, a controlling function 150b, an acquiring function 150c, a calculating function 150d, and the generating function 150e.

In an embodiment, processing functions performed by the interface function 150a, the controlling function 150b, the acquiring function 150c, the calculating function 150d, and the generating function 150e are stored in the storage 132 in the form of computer-executable programs. The processing circuitry 150 is a processor configured to realize the functions corresponding to the programs by reading and executing the programs from the storage 132. In other words, the processing circuitry 150 that has read the programs has the functions illustrated within the processing circuitry 150 in FIG. 1. FIG. 1 illustrates the example in which the single processing circuitry (i.e., the processing circuitry 150) realizes the processing functions performed by the interface function 150a, the controlling function 150b, the acquiring function 150c, the calculating function 150d, and the generating function 150e; however, another arrangement is also acceptable in which the processing circuitry 150 is structured by combining together a plurality of independent processors, so that the functions are realized as a result of the processors executing the programs.

In other words, each of the abovementioned functions may be structured as a program, so that one processing circuitry executes the programs. Alternatively, one or more specific functions each may be installed in a dedicated independent program-executing circuit.

The term “processor” used in the above explanation denotes, for example, a Central Processing Unit (CPU), a Graphical Processing Unit (GPU), or a circuit such as an Application Specific Integrated Circuit (ASIC) or a programmable logic device (e.g., a Simple Programmable Logic Device [SPLD], a Complex Programmable Logic Device [CPLD], or a Field Programmable Gate Array [FPGA]). The one or more processors realize the functions by reading and executing the programs stored in the storage 132.

In this situation, the calculating function 150d and the generating function 150e are examples of the calculating unit and the generating unit, respectively. Similarly, the sequence controlling circuitry 120 is an example of the sequence controlling unit.

Further, instead of saving the programs in the storage 132, it is also acceptable to directly incorporate the programs in the circuits of the processors. In that situation, the processors realize the functions thereof by reading and executing the programs incorporated in the circuits thereof. Similarly, the couch controlling circuitry 106, the transmitter circuitry 108, the receiver circuitry 110, and the like are also each configured with an electronic circuit such as the processor defined above.

By employing the interface function 150a, the processing circuitry 150 is configured to transmit the sequence information to the sequence controlling circuitry 120 and to receive the magnetic resonance data from the sequence controlling circuitry 120. Further, when having received the magnetic resonance data, the processing circuitry 150 having the interface function 150a stores the received magnetic resonance data into the storage 132. The magnetic resonance data stored in the storage 132 is arranged into the k-space by the controlling function 150b. As a result, the storage 132 has stored the k-space data therein.

Similarly, by employing the interface function 150a, the processing circuitry 150 is configured to obtain the current value from the ammeter 160. Further, when having obtained the current value from the ammeter 160, the processing circuitry 150 stores the received data into the storage 132, as necessary.

The storage 132 is configured to store therein the magnetic resonance data received by the processing circuitry 150 having the interface function 150a; the k-space data arranged into the k-space by the processing circuitry 150 having the controlling function 150b; image data generated by the processing circuitry 150 having the generating function 150e; the current value obtained from the ammeter 160; and the like. For example, the storage 132 is configured with a semiconductor memory element such as a Random Access Memory (RAM), a flash memory, or the like, or a hard disk, an optical disk, or the like.

The input device 134 is configured to receive inputs of various types of instructions and information from the operator. The input device 134 is, for example, a pointing device such as a mouse and/or a trackball; a selecting device such as a mode changing switch; and/or an input device such as a keyboard. The display 135 is configured to display, under control of the processing circuitry 150 having the controlling function 150b, a Graphical User Interface (GUI) used for receiving inputs of image taking conditions, as well as images generated by the processing circuitry 150 having the generating function 150e, and the like. The display 135 is, for example, a display device configured with a liquid crystal display monitor, or the like.

By employing the controlling function 150b, the processing circuitry 150 is configured to control image taking processes, image generating processes, image display processes, and the like, by exercising overall control of the magnetic resonance imaging apparatus 100. For example, the processing circuitry 150 having the controlling function 150b receives an input of an image taking condition (e.g., an image taking parameter or the like) via the GUI and generates sequence information according to the received image taking condition. Further, the processing circuitry 150 having the controlling function 150b transmits the generated sequence information to the sequence controlling circuitry 120.

By employing the generating function 150e, the processing circuitry 150 is configured to generate an image (r-space data) by reading the k-space data from the storage 132 and performing a reconstructing process such as a Fourier transform on the read k-space data.

When performing the image generating process, the processing circuitry 150 may perform one or more of the following processes: a regridding process; a nyquist ghost correction; a motion correction; and other k-space filtering processes. In this situation, the regridding process is a process to re-arrange sampled data into the k-space at regular intervals and may be implemented by using a cubic spline interpolation or the like, for example. To be more specific, as understood from Expression (1), when the gradient magnetic field temporally changes, the data sampled at temporal regular intervals is not sampled at regular intervals in the k-space. Accordingly, the regridding process is a predetermined process performed for the purpose of generating data that is arranged at regular intervals in the k-space.

Further, the processing circuitry 150 includes other various types of functions such as the acquiring function 150c and the calculating function 150d. These functions will be explained later.

Next, a background of the present embodiment will be briefly explained. FIG. 3 is a drawing for explaining a data processing process performed by a magnetic resonance imaging apparatus according to a conventional technique. A region 2 in FIG. 3 is an enlarged view of the region 2 in FIG. 2. In other words, patches 2a, 2b, and 2c correspond to a part of the k-space data acquired by using the first RF pulse, a part of the k-space data acquired by using the second RF pulse, and a part of the k-space data acquired by using the third RF pulse, respectively. Accordingly, the patches 2a, 2b, and 2c are pieces of k-space data corresponding to a part of the trajectory 1a, a part of the trajectory 1b, and a part of the trajectory 1c in FIG. 2, respectively.

According to the conventional technique, as illustrated in the bottom section of FIG. 3, when generating the second k-space data by combining together the acquired plurality of segments in the first-k-space data, the processing circuitry 150 would generate the second k-space data by using, in the combining process, two or more of the acquired pieces of first k-space data with respect to the k-space acquired in the overlapping manner. For example, as illustrated in the bottom section of FIG. 3, according to the conventional technique, the processing circuitry 150 would generate the second k-space data, by using the k-space data of the patch 2a, which is the k-space data acquired by using the first RF pulse, with respect to a region 3a; by using the k-space data of the patch 2b, which is the k-space data acquired by using the second RF pulse, with respect to a region 3b; and by using the k-space data of the patch 2c, which is the k-space data acquired by using the third RF pulse, with respect to a region 3c.

According to this method, however, the k-space data would have discontinuity around the vicinity of the boundary between the region 3a and the region 3b and the vicinity of the boundary between the region 3b and the region 3c, for example. As a result, the quality of the image to be output would be degraded.

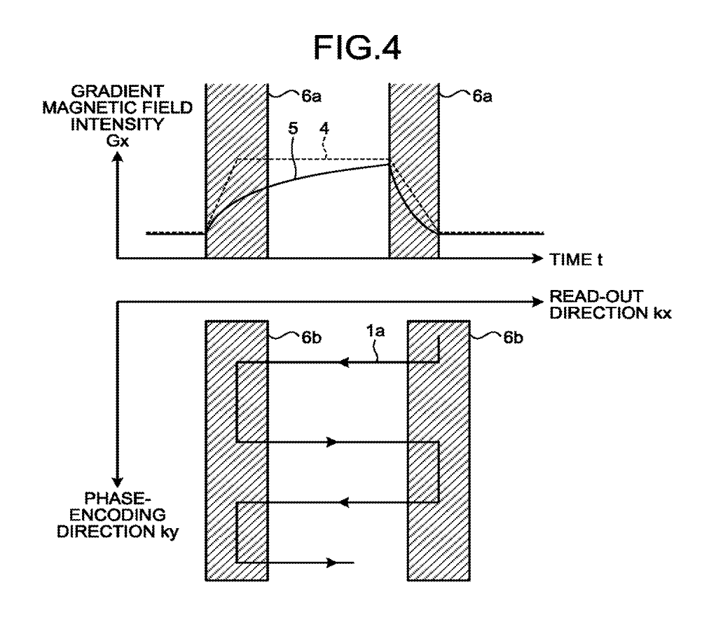

This aspect will be explained with reference to FIG. 4. FIG. 4 is a drawing for explaining a background of the magnetic resonance imaging apparatus according to the present embodiment.

In the top section of FIG. 4, the horizontal axis expresses time t, whereas the vertical axis expresses the gradient magnetic field intensity Gₓ in the read-out direction. A model waveform 4 is a model waveform of the gradient magnetic field Gₓ in the read-out direction, which is drawn as a trapezoidal waveform in FIG. 4. In the top section of FIG. 4, the model waveform 4 has a flat part in which the waveform is flat and ramp parts corresponding to a rising region and a falling region of the gradient magnetic field intensity Gₓ. As explained below, the quality of the data acquired by the sequence controlling circuitry 120 is higher in the flat part and, conversely, is lower in the ramp parts. Further, in the top section of FIG. 4, a gradient magnetic field waveform 5 represents an actual waveform of the gradient magnetic field Gₓ in the read-out direction. In the bottom section of FIG. 4, the model waveform 4 and the gradient magnetic field waveform 5 each correspond to one line in the read-out direction (starting from one end in the read-out direction up to where the line reaches and turns back at the other end in the read-out direction).

The model waveform 4, which is an input waveform input to the gradient power source 104 by the sequence controlling circuitry 120 is, in actuality, different from the waveform of the gradient magnetic field waveform 5 due to a non-linear effect. However, because it is sometimes difficult to precisely calculate the gradient magnetic field waveform 5, it may also be difficult, in some situations, to precisely evaluate the impact of the non-linear effect on the acquired data quantitatively. For this reason, in a ramp region 6a illustrated in the top section of FIG. 4, the level of precision of the data is degraded. The ramp region 6a illustrated in the top section of FIG. 4 corresponds to a ramp region 6b displayed in the k-space. In other words, in the regions acquired in the overlapping manner, the level of precision of the data is degraded.

To summarize, according to the conventional technique, with respect to the k-space acquired in the overlapping manner, the second k-space data is generated by combining together two or more of the acquired segments. As a result, according to the conventional technique, the k-space data has discontinuity.

In view of the background as explained above, in the magnetic resonance imaging apparatus 100 according to the present embodiment, the sequence controlling circuitry 120 is configured to acquire the first k-space data in the plurality of segments while arranging the segments to overlap one another in the read-out direction. By employing the calculating function 150d, the processing circuitry 150 is configured to calculate the weighting coefficient on the basis of the information about the gradient magnetic field related to the acquisition. By employing the generating function 150e, the processing circuitry 150 is configured to generate the second k-space data on the basis of the plurality of segments in the first k-space data and the weighting coefficient. In other words, the magnetic resonance imaging apparatus 100 according to the embodiment is configured to calculate the weighting coefficient with respect to the position, in the k-space, of each of the segments acquired in the overlapping manner and to generate the second k-space data on the basis of the calculated weighting coefficients.

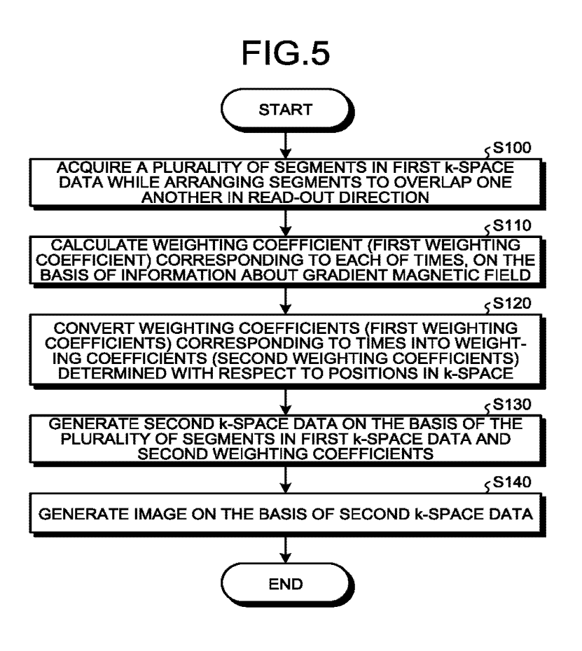

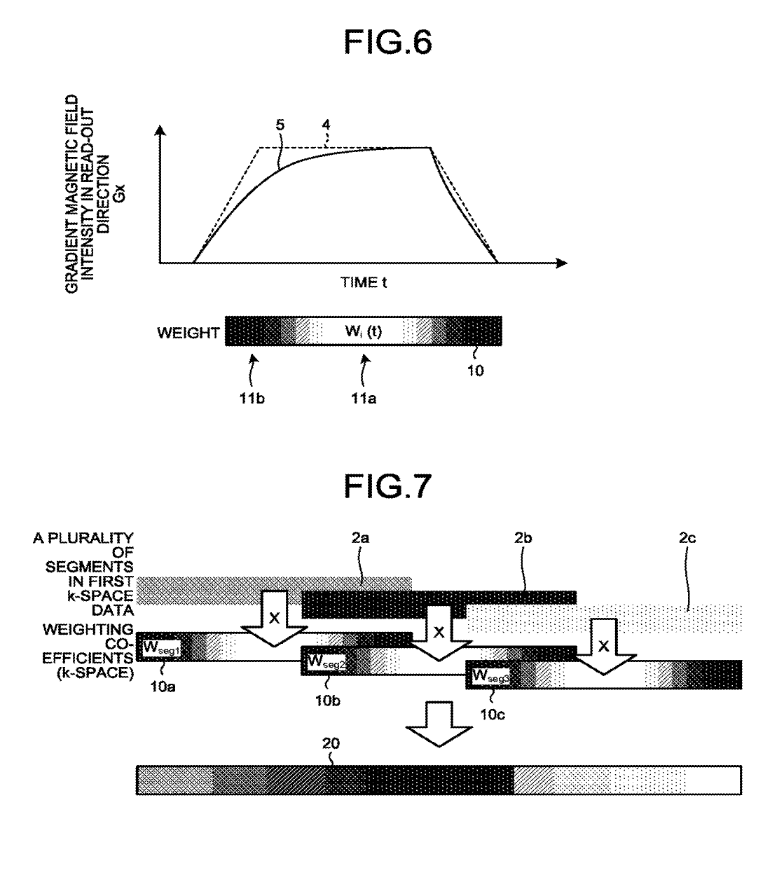

The abovementioned configuration will be explained, with reference to FIGS. 5 to 7. FIG. 5 is a flowchart for explaining a procedure in a process performed by the magnetic resonance imaging apparatus according to the embodiment. FIGS. 6 and 7 are drawings for explaining a weighting process performed by the magnetic resonance imaging apparatus according to a first embodiment.

At step S100, the sequence controlling circuitry 120 acquires the first k-space data in units of the plurality of segments while arranging the segments to overlap one another in the read-out direction by implementing the RSEPI method, for example. By employing the acquiring function 150c, the processing circuitry 150 obtains the acquired first k-space data in units of the plurality of segments, from the sequence controlling circuitry 120.

Subsequently, at step S110, by employing the calculating function 150d, the processing circuitry 150 calculates a weighting coefficient wᵢ(t) (a first weighting coefficient) corresponding to an i'th acquisition and to each of the times t, on the basis of information about the gradient magnetic field, e.g., the waveform of the gradient magnetic field. In this situation, the i'th acquisition denotes an acquisition related to the excitation by an i'th RF pulse. For example, in FIG. 2, the acquisition related to the trajectory 1a, the acquisition related to the trajectory 1b, and the acquisition related to the trajectory 1c correspond to the first acquisition, the second acquisition, and the third acquisition, respectively.

FIG. 6 is a drawing for explaining the process of determining the weighting coefficient wᵢ(t) performed by the magnetic resonance imaging apparatus according to the first embodiment. In FIG. 6, the horizontal axis expresses time t, whereas the vertical axis expresses the gradient magnetic field intensity Gₓ in the read-out direction. The model waveform 4 denotes the waveform of a control signal input to the gradient power source 104 by the sequence controlling circuitry 120. In FIG. 6, the model waveform is a trapezoidal waveform. Further, the gradient magnetic field waveform 5 is a gradient magnetic field waveform calculated by the processing circuitry 150 by employing the calculating function 150d, while using a simulation that uses a predetermined equivalent circuit or the like, on the basis of the actual waveform of the gradient magnetic field, e.g., the waveform of an electric current measured by the ammeter 160, for example. As the equivalent circuit, for example, an equivalent circuit structured with a closed circuit including a coil corresponding to the gradient coil and another closed circuit magnetically linked to the closed circuit may be used.

These pieces of information about the gradient magnetic field (the model waveform 4 and the gradient magnetic field waveform 5, or the like) may be obtained in advance prior to the execution of the pulse sequence related to the image taking process. Further, these pieces of information about the gradient magnetic field may be calculated only through a simulation on a computer or the like or may be obtained, conversely, as a measured value by a measuring device through, for example, a measuring process that uses the ammeter 160. In this situation, the terms “measured” and “measuring” do not necessarily require that the measuring process is performed in a real-time manner during the image taking process; however, the measuring process may be performed in a real-time manner during the image taking process.

As a method for calculating the weighting coefficient wᵢ(t), by employing the calculating function 150d, the processing circuitry 150 calculates the weighting coefficient wᵢ(t) corresponding to each of the times t, on the basis of the intensity of the gradient magnetic field at the time. In this situation, the “intensity of the gradient magnetic field at (each of) the time” denotes the gradient magnetic field waveform 5 illustrated in FIG. 6, for example. As an example of the weighting coefficient wᵢ(t), by employing the calculating function 150d, the processing circuitry 150 calculates the weighting coefficient wᵢ(t) on the basis of the intensity of the gradient magnetic field corresponding to each of the times and a maximum value of the intensities of the gradient magnetic field. More specifically, by employing the calculating function 150d, the processing circuitry 150 calculates the weighting coefficient wᵢ(t) related to the i'th acquisition by using Expression (3) presented below, for example.

$${w}_{i} ( t ) = \frac{\vert {G}_{x} ( t ) \vert}{{max}_{t} \vert {G}_{x} ( t ) \vert} \qquad ( 3 )$$

In Expression (3), t denotes time whereas Gₓ(t) denotes the gradient magnetic field intensity in the read-out direction at the time t, e.g., the gradient magnetic field waveform 5 illustrated in FIG. 6.

The denominator on the right-hand side of Expression (3) is a normalization constant used for adjusting the values of the weighting coefficients between mutually-different acquisitions. Further, as observed from the numerator on the right-hand side of Expression (3), the larger the absolute value of the gradient magnetic field intensity, the larger is the value of the weighting coefficient wᵢ(t). In actuality, when the gradient magnetic field intensity has a maximum value, the weighting coefficient wᵢ(t) is equal to 1. On the contrary, when the gradient magnetic field intensity is equal to 0, the weighting coefficient wᵢ(t) is equal to 0.

In the bottom section of FIG. 6, a qualitative behavior of a weighting coefficient 10 is illustrated. In FIG. 6, the whiter the color is, the larger is the value of the weighting coefficient wᵢ(t). Conversely, the darker the color is, the smaller is the value of the weighting coefficient wᵢ(t). As illustrated in the drawings, the weighting coefficient wᵢ(t) exhibits larger values in a flat part 11a where the gradient magnetic field intensity is constant and does not change. In contrast, the weighting coefficient wᵢ(t) exhibits smaller values in a ramp parts 11b where the value of the gradient magnetic field intensity changes. In other words, the weighting coefficient wᵢ(t) exhibits larger values in the flat part 11a where the difference between the model waveform 4 and the gradient magnetic field waveform 5 is smaller and the reliability of the data is higher. In contrast, the weighting coefficient wᵢ(t) exhibits smaller values in the ramp parts 11b where the difference between the model waveform 4 and the gradient magnetic field waveform 5 is larger and the reliability of the data is lower. By employing the calculating function 150d, the processing circuitry 150 calculates the weighting coefficients in such a manner that the weighting coefficients corresponding to times during the rising or the falling time periods (during the ramps) of the gradient magnetic field are smaller than the weighting coefficients corresponding to times during the time period other than the rising and the falling time periods (during the ramps) of the gradient magnetic field.

Subsequently, at step S120, by employing the calculating function 150d, the processing circuitry 150 converts the weighting coefficient wᵢ(t) (the first weighting coefficient) corresponding to each of the times into a weighting coefficient wᵢ(p) (a second weighting coefficient) determined with respect to each of the positions in the k-space. More specifically, by employing the calculating function 150d, the processing circuitry 150 calculates, as a weighting coefficient used for generating the second k-space data, the second weighting coefficient wᵢ(p) determined with respect to each of the overlapping positions in the k-space, on the basis of the weighting coefficient wᵢ(t) corresponding to each of the times (the first weighting coefficient) and the correspondence relationship (the correspondence relationship defined by Expression (2)) between the times t and the positions in the k-space in which the pieces of data are acquired at the times t during the application of the gradient magnetic field. In other words, by using Expression (2), the processing circuitry 150 converts the weighting coefficient wᵢ(t) corresponding to each of the times, into the second weighting coefficient wᵢ(p) determined with respect to each of the overlapping positions in the k-space.

In other words, by placing a focus on the correspondence relationship between the times t and the positions in the k-space in which the pieces of data are acquired at the times t during the application of the gradient magnetic field, it is possible to generate the weighting coefficients in the k-space while using the waveform of the gradient magnetic field intensity. On the basis of this background, by employing the calculating function 150d, the processing circuitry 150 calculates, by performing the processes at steps S110 and S120, the weighting coefficient determined with respect to each of the overlapping positions in the k-space, on the basis of the waveform of the gradient magnetic field and the correspondence relationship between the times and the positions in the k-space in which the pieces of data are acquired at the times during the application of the gradient magnetic field.

After that, at step S130, by employing the generating function 150e, the processing circuitry 150 generates the second k-space data on the basis of the plurality of segments sᵢ(p) in the first k-space data and the second weighting coefficient wᵢ(p). More specifically, by employing the generating function 150e with respect to such a position in the k-space that is not overlapping, i.e., such a position in the k-position that has only one piece of data, the processing circuitry 150 generates the second k-space data by using the one piece of data without any modification. In contrast, by employing the generating function 150e, the processing circuitry 150 generates the second k-space data S(p) by performing a process expressed by Expression (4) presented below with respect to a position p in the k-space that is overlapping.

$$S ( p ) = \frac{{\sum }_{i = 1}^{N} \{ {w}_{i} \cdot {s}_{i} ( p ) \}}{{\sum }_{i = 1}^{N} {w}_{i}} \qquad ( 4 )$$

In Expression (4), i denotes an i'th acquisition, whereas N denotes a total number of times of acquisitions. The symbol wᵢ denotes the second weighting coefficient wᵢ(p) in the position p in the k-space, whereas the symbol sᵢ denotes the first k-space data sᵢ(p) in the position p in the k-space.

The situation described above is illustrated in FIG. 7. FIG. 7 is a drawing for explaining a weighting process performed by the magnetic resonance imaging apparatus according to the first embodiment. In FIG. 7, the patches 2a, 2b, and 2c correspond to pieces of k-space data related to the first RF pulse, the second RF pulse, and the third RF pulse, respectively. The patches 2a, 2b, and 2c are examples of the plurality of segments in the first k-space data. With respect to the patches 2a, 2b, and 2c, weighting coefficients 10a, 10b, and 10c are respectively determined in correspondence with the positions in the k-space, as a result of the process at step S120. Subsequently, in locations where the first k-space data is not overlapping, the first k-space data is used as second k-space data 20 without any modification. In locations where the first k-space data is overlapping, a linear sum of the first k-space data and the weighting coefficient is calculated according to Expression (4), so as to generate second k-space data.

Subsequently, at step S140, by employing the generating function 150e, the processing circuitry 150 generates an image to be output, on the basis of the second k-space data generated at step S130. More specifically, the processing circuitry 150 generates r-space data by performing a Fourier transform on the second k-space data.

As explained above, in the first embodiment, the processing circuitry 150 is configured to generate the second k-space data from the plurality of segments in the first k-space data, by using the weighting coefficients that uses the waveform of the gradient magnetic field. As a result, the generated second k-space data has less discontinuity. The quality of the image to be output is therefore improved.

Further, possible embodiments are not limited to the example described above. As the method for calculating the weighting coefficient wᵢ(t) at step S110, any of other various methods can be used. As for the gradient magnetic field waveform 5 used for calculating the weighting coefficient wᵢ(t), the processing circuitry 150 may calculate the weighting coefficient wᵢ(t) by employing the calculating function 150d, while using the value of the electric current flowing in the gradient coil 103 in place of Gₓ(t) in Expression (3), on the assumption that the waveform of the gradient magnetic field is similar to the electric current (the output current) flowing in the gradient coil 103. In that situation, the value of the electric current flowing in the gradient coil 103 may be a value of the electric current measured by the ammeter 160 or may be a value of the electric current calculated through a simulation on the basis of the model waveform 4 (the input waveform).

Further, as another example of the method for calculating the weighting coefficient wᵢ(t), it is also acceptable to calculate the weighting coefficient wᵢ(t) by using the model waveform 4 instead of the gradient magnetic field waveform 5, i.e., by using the value of the electric current in the waveform of the control signal input to the gradient power source 104 by the sequence controlling circuitry 120 in place of Gₓ(t) in Expression (3). In that situation, the model waveform 4 may be a trapezoidal waveform or may be a rectangular waveform that is more simplified. Further, as the model waveform 4, it is also acceptable to use a control signal incorporating, to some extent, effects of an electromotive force and an eddy current caused by changes in the electric current. Further, it is also acceptable to use the waveform of an output current or the like under such a control signal, as the gradient magnetic field waveform 5 used for calculating the weighting coefficient wᵢ(t).

Further, the method for calculating the weighting coefficient wᵢ(t) is not limited to the one expressed in Expression (3) presented above, and it is possible to use any of other various methods. For instance, by employing the calculating function 150d, the processing circuitry 150 may calculate the weighting coefficient wᵢ(t), simply on the basis of only the magnitude of the gradient magnetic field waveform 5. For example, by employing the calculating function 150d, the processing circuitry 150 may calculate the weighting coefficient wᵢ(t) on the basis of the numerator on the right-hand side of Expression (3), by eliminating the normalization constant in the denominator of Expression (3). Alternatively, by employing the calculating function 150d, the processing circuitry 150 may calculate a weighting coefficient wᵢ(t) that is binarized. For example, by employing the calculating function 150d, the processing circuitry 150 may calculate a weighting coefficient wᵢ(t) that is equal to 1 when the magnitude of the gradient magnetic field is greater than a predetermined threshold value and is equal to 0 when the magnitude of the gradient magnetic field is not greater than the predetermined threshold value. Further, the processing circuitry 150 may calculate a weighting coefficient wᵢ(t) by using a function form structured in such a manner that the larger the absolute value of the intensity of the gradient magnetic field being applied is, the larger is the weight. Further, the processing circuitry 150 may calculate a weighting coefficient wᵢ(t) in accordance with the degree of distortion of the gradient magnetic field waveform being applied. Further, the processing circuitry 150 may simply use the time t as a weighting coefficient wᵢ(t).

To calculate the weighting coefficient wᵢ(t), when the gradient magnetic field waveform is the same for a plurality of lines, it is possible to diversely use the weighting coefficient wᵢ(t) of one of the lines as a weighting coefficient wᵢ(t) of the other lines. For example, with respect to a plurality of lines of which the gradient magnetic field waveforms are mutually the same while only the polarities thereof are different, it is possible to diversely use the weighting coefficient wᵢ(t) of one of the lines as a weighting coefficient wᵢ(t) of the other lines.

Further, as for the process of generating the second k-space data at step S130, possible embodiments are not limited to the example described above. For instance, in Expression (4), the weighting coefficient wᵢ may be normalized by being binarized. In that situation, for example, at each of the points, the weighting coefficient wᵢ having the largest weight is equal to 1, while the other weighting coefficients wᵢ are equal to 0.

Further, with respect to data points in which the value of the data itself is equal to 0 or close to 0, the processing circuitry 150 may set the weighting coefficient wᵢ to 0 by employing the calculating function 150d.

Further, as presented in Expression (4), the example is explained in which, with respect to the first k-space data sᵢ(p) expressed with the complex number, a weighted average is calculated by simply using the weighting coefficient wi; however, possible embodiments are not limited to this example. For instance, when a weighted average is calculated with respect to the first k-space data sᵢ(p) expressed with the complex number, it is also acceptable to generate the second k-space data S(p), by multiplying the phase of such a piece of data having the largest weight among the pieces of first k-space data sᵢ(p) by a weighted average calculated by using the weighting coefficient wi on the absolute values |sᵢ(p)| of the pieces of first k-space data sᵢ(p).

### Second Embodiment

In the first embodiment, the example is explained in which, by employing the calculating function 150d, the processing circuitry 150 calculates the weighting coefficient on the basis of the magnitude of the gradient magnetic field. Because the part having a gradient magnetic field of the greater magnitude is the flat part where the level of precision of the data is higher, whereas the parts having a gradient magnetic field of the smaller magnitude is the ramp parts where the level of precision of the data is lower, it is possible to enhance the quality of the image by adopting such a weighting coefficient that exhibits larger values when the magnitudes of the gradient magnetic field are greater. In contrast, in a second embodiment, an example will be explained in which, by employing the calculating function 150d, the processing circuitry 150 calculates a weighting coefficient on the basis of a difference between the intensities of the gradient magnetic field corresponding to times (e.g., the gradient magnetic field waveform 5) and model values (e.g., the model waveform 4) for the intensities of the gradient magnetic field corresponding to the times.

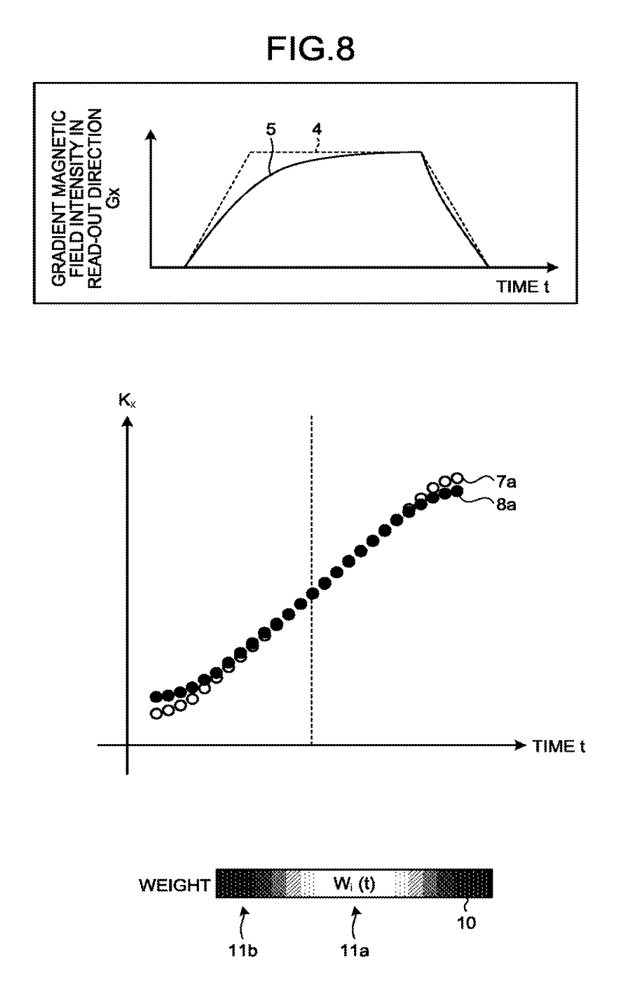

In the second embodiment, in the flowchart illustrated in FIG. 5, the processes other than the process at step S110 are the same as those in the first embodiment. At step S110, according to the second embodiment, the processing circuitry 150 calculates, by employing the calculating function 150d, a weighting coefficient on the basis of the intensities of the gradient magnetic field corresponding to the times and the model values for the intensities of the gradient magnetic field corresponding to the times. This situation is illustrated in FIG. 8. FIG. 8 is a drawing for explaining the weighting coefficient calculating process performed by a magnetic resonance imaging apparatus 100 according to the second embodiment. Similarly to FIG. 6, the top section of FIG. 8 illustrates the model waveform 4 and the gradient magnetic field waveform 5. In this situation, the model waveform 4 is the waveform of the control signal input to the gradient power source 104 by the sequence controlling circuitry 120 and exhibits model values for the intensities of the gradient magnetic field corresponding to the times. In FIG. 8, the model waveform is a trapezoidal waveform. Further, the gradient magnetic field waveform 5 is an actual waveform of the gradient magnetic field, e.g., a waveform similar to the waveform of the electric current obtained by the processing circuitry 150 from the ammeter 160 by employing the acquiring function 150c or a gradient magnetic field waveform calculated by the processing circuitry 150 by employing the calculating function 150d while using a simulation that uses a predetermined equivalent circuit or the like, for example, on the basis of the waveform of the electric current measured by the ammeter 160. The gradient magnetic field waveform 5 corresponds to the intensities of the gradient magnetic field at the times.

Similarly to the first embodiment, these pieces of information about the gradient magnetic field (the model waveform 4 and the gradient magnetic field waveform 5, or the like) may be obtained in advance prior to the execution of the pulse sequence related to the image taking process. Further, these pieces of information about the gradient magnetic field may be calculated only through a simulation on a computer or the like or may be obtained, conversely, as a measured value by a measuring device through, for example, a measuring process that uses the ammeter 160. In this situation, similarly to the first embodiment, the terms “measured” and “measuring” do not necessarily require that the measuring process is performed in a real-time manner during the image taking process; however, the measuring process may be performed in a real-time manner during the image taking process.

By employing the calculating function 150d, the processing circuitry 150 calculates a first weighting coefficient wᵢ(t) at step S110, on the basis of the model waveform 4 and the gradient magnetic field waveform 5 by using Expression (5).

$${w}_{i} ( t ) = 1 - \frac{\vert {K}_{x} ( t ) - {K}_{x 0} ( t ) \vert}{{max}_{t} \vert {K}_{x} ( t ) - {K}_{x 0} ( t ) \vert} \qquad ( 5 )$$

In Expression (5), Kₓ₀(t) expresses a position in the k-space corresponding to the time t in the model waveform 4. Kₓ₀(t) is a value obtained by evaluating the right-hand side of Expression (2), by assigning the gradient magnetic field intensity Gₓ in the read-out direction in the model waveform 4 to Gₓ on the right-hand side of Expression (2). Further, Kₓ(t) expresses a position in the k-space corresponding to the time t in the gradient magnetic field waveform 5. Kₓ(t) is a value obtained by evaluating the right-hand side of Expression (2), by assigning the gradient magnetic field intensity Gₓ in the read-out direction in the gradient magnetic field waveform 5 to Gₓ on the right-hand side of Expression (2).

In this situation, the weighting coefficient wᵢ(t) in Expression (5) is a weighting coefficient that exhibits a maximum value 1 when Kₓ(t)=Kₓ₀(t) is satisfied and that, conversely, exhibits a minimum value 0 when the difference between Kₓ(t) and Kₓ₀(t) is the largest. Accordingly, the weighting coefficient calculated at step S110 by the processing circuitry 150 while employing the calculating function 150d is a weighting coefficient that exhibits the maximum value when the difference between the model waveform 4 and the gradient magnetic field waveform 5 is the smallest and that exhibits the minimum value when the difference between the model waveform 4 and the gradient magnetic field waveform 5 is the largest.

This situation is illustrated in the middle and the bottom sections of FIG. 8. A chart 7a expresses the position Kₓ₀(t) in the k-space corresponding to the time t in the model waveform 4 as a mathematical function of the time t. Further, a chart 8a expresses the position Kₓ(t) in the k-space corresponding to the time t in the gradient magnetic field waveform 5 as a mathematical function of the time t. Further, the bottom section of FIG. 8 illustrates, in a box 10, a distribution of the values of the weighting coefficient wᵢ(t). In the bottom section of FIG. 8, the whiter the color is, the larger is the value of the weighting coefficient wᵢ(t). Conversely, the darker the color is, the smaller is the value of the weighting coefficient wᵢ(t). As understood from FIG. 8, in the flat part 11a where the difference between the model waveform 4 and the gradient magnetic field waveform 5 (accordingly, the difference between the chart 7a and the chart 8a) is smaller, the value of the weighting coefficient wᵢ(t) is larger. In contrast, in the ramp parts 11b where the difference between the model waveform 4 and the gradient magnetic field waveform 5 is larger, the value of the weighting coefficient wᵢ(t) is smaller. Consequently, the weighting coefficient wᵢ(t) according to the second embodiment is configured to be able to make the weights larger in the flat part 11a where the quality of the data is higher and to make the weights smaller in the ramp parts 11b where errors are more likely to occur. It is therefore possible to enhance the quality of the output image.

As for the processes at step S120 and thereafter, the same processes as those in the first embodiment will be performed.

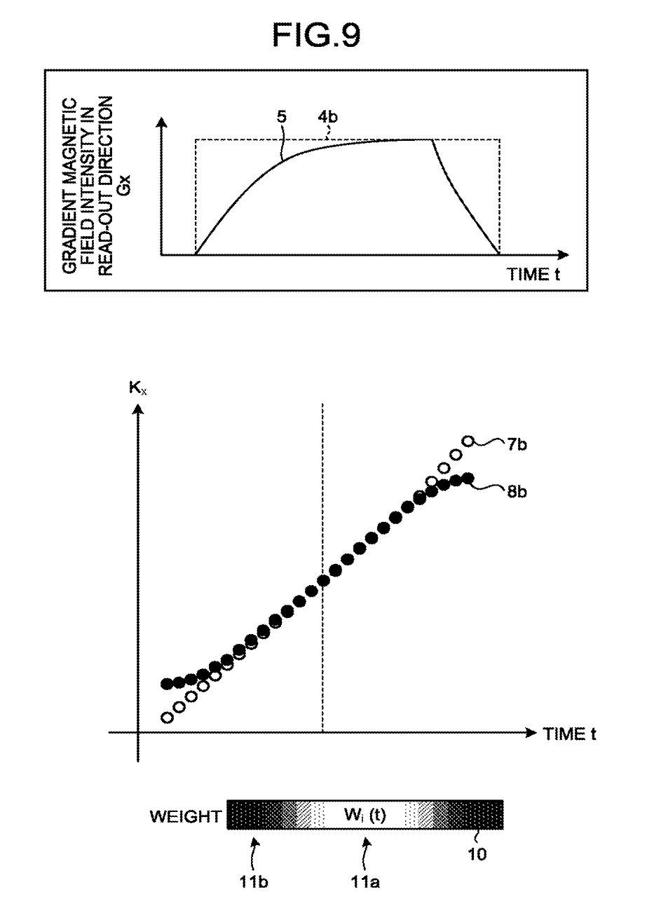

Possible embodiments are not limited to the example described above. For instance, in place of the trapezoidal waveform, the processing circuitry 150 may select a simpler rectangular waveform as the model waveform 4. FIG. 9 illustrates this situation. FIG. 9 is a drawing for explaining another weighting coefficient calculating process performed by the magnetic resonance imaging apparatus according to the second embodiment.

In FIG. 9, a rectangular waveform is selected as a model waveform 4b. In the middle section of FIG. 9, a chart 7b expresses a position Kₓ₀(t) in the k-space corresponding to the time t in the model waveform 4b as a mathematical function of the time t. Further, a chart 8b expresses a position Kₓ(t) in the k-space corresponding to the time t in the gradient magnetic field waveform 5 as a mathematical function of the time t. Further, the bottom section of FIG. 9 illustrates, in a box 10, a distribution of the values of the weighting coefficient wᵢ(t). Similarly to FIG. 8, FIG. 9 also indicates that in the flat part 11a where the difference between the model waveform 4b and the gradient magnetic field waveform 5 (accordingly, the difference between the chart 7b and the chart 8b) is smaller, the value of the weighting coefficient wᵢ(t) is larger. In contrast, in the ramp parts 11b where the difference between the model waveform 4b and the gradient magnetic field waveform 5 is larger, the value of the weighting coefficient w(t) is smaller. Consequently, the weighting coefficient wᵢ(t) according to the second embodiment is configured to be able to make the weights larger in the flat part 11a where the quality of the data is higher and to make the weights smaller in the ramp parts 11b where errors are more likely to occur. It is therefore possible to enhance the quality of the output image.

Further, similarly to the first embodiment, the processing circuitry 150 may use, as the model waveform 4, a control signal incorporating, to some extent, effects of an electromotive force and an eddy current caused by changes in the electric current. Further, it is also acceptable to use the waveform of an output current or the like under such a control signal, as the gradient magnetic field waveform 5 used for calculating the weighting coefficient wᵢ(t).

Further, possible function forms for the weighting coefficient wᵢ(t) include other various function forms besides the one in the above example. For instance, by employing the calculating function 150d, the processing circuitry 150 may calculate a weighting coefficient wᵢ(t) by using another function form structured in such a manner that the larger the difference between the model waveform 4 and the gradient magnetic field waveform 5 is, the smaller is the weighting coefficient wᵢ(t).

As explained above, in the second embodiment, by employing the calculating function 150d, the processing circuitry 150 is configured to calculate the weighting coefficient on the basis of the difference between the intensity of the gradient magnetic field corresponding to each of the times and the model value for the intensity of the gradient magnetic field corresponding to each of the times. With this arrangement, it is possible to arrange the weighting coefficient to be larger for the region in which the difference between the model waveform 4 and the gradient magnetic field waveform 5 is smaller and in which the reliability of the data is higher and, conversely, to arrange the weighting coefficient to be smaller for the region in which the difference between the model waveform 4 and the gradient magnetic field waveform 5 is larger and in which the reliability of the data is lower. The weighting coefficients using the difference between the model waveform 4 and the gradient magnetic field waveform 5 is able to detect the magnitude of the non-linear effect more sensitively than the weighting coefficients using only one selected from between the model waveform 4 and the gradient magnetic field waveform 5. It is therefore possible to enhance the quality of the output image.

### <Computer Programs>

The instructions indicated in the processing procedures explained in the embodiments above may be executed on the basis of a computer program (hereinafter, “program”) realized with software. By causing a generic computer to store the program therein in advance and to read the program, it is also possible to achieve the same advantageous effects as those achieved by the magnetic resonance imaging apparatus 100 according to any of the embodiments described above. The instructions described in the embodiments above may be recorded as a computer-executable program on a magnetic disk (a flexible disk, a hard disk, or the like), an optical disk (a Compact Disk Read-Only Memory [CD-ROM], a Compact Disc Recordable [CD-R], a Compact Disk Rewritable [CD-RW], a Digital Versatile Disk Read-Only Memory [DVD-ROM], a DVD Recordable [DVD±R], a DVD Rewritable [DVD±RW], or the like), a semiconductor memory, or a similar recording medium. As long as the storage medium is readable by a computer or an embedded system, any storage format may be used. By reading the program from such a recording medium and causing a CPU to execute the instructions written in the program on the basis of the program, the computer is able to realize the same operations as those performed by the magnetic resonance imaging apparatus 100 of any of the embodiments described above. Further, when obtaining or reading the program, the computer may obtain or read the program via a network.

Furthermore, a part of the processes that realize any of the embodiments described above may be performed by an Operating System (OS) working in a computer or middleware (MW) such as database management software or a network, on the basis of the instructions in the program installed in a computer or an embedded system from a storage medium. Further, the storage medium does not necessarily have to be a medium independent of the computer or the embedded system and may be a storage medium downloading and storing or temporarily storing therein the program transmitted via a Local Area Network (LAN), the Internet, or the like. Further, the number of storage media being used does not necessarily have to be one. The storage medium according to the embodiments includes the situation where the processes according to the embodiments are executed from two or more media. The medium or media can have any configuration.

The computer or the embedded system according to the embodiments is configured to execute the processes in the embodiments on the basis of the program stored in the storage medium and may be realized with any configuration that uses a single apparatus such as a personal computer, a microcomputer or the like, or a system in which a plurality of apparatuses are connected together via a network. Furthermore, the computer according to the embodiments does not necessarily have to be a personal computer, and may be an arithmetic processing device or a microcomputer included in an information processing device, or the like. The term “computer” is a generic term for any of various devices and apparatuses that are each able to realize the functions described in the embodiments by using the program.

As explained above, according to at least one aspect of the embodiments, it is possible to provide a magnetic resonance imaging apparatus capable of enhancing the image quality while implementing a magnetic resonance imaging method by which data is acquired by using the RF pulse applied multiple times.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
sequence controlling circuitry configured to acquire first k-space data in units of a plurality of segments while arranging the plurality of segments to overlap one another in a read-out direction, the first k-space being divided into the plurality of segments in the read-out direction;
processing circuitry configured to calculate a weighting coefficient on a basis of information about a gradient magnetic field related to the acquisition; and configured to generate second k-space data on a basis of the plurality of segments in the first k-space data and the weighting coefficient.

2. The magnetic resonance imaging apparatus according to claim 1, wherein the processing circuitry is configured to calculate the weighting coefficient on a basis of a waveform of the gradient magnetic field.

3. The magnetic resonance imaging apparatus according to claim 1, wherein the processing circuitry is configured to calculate the weighting coefficient on a basis of an intensity of the gradient magnetic field corresponding to each of a plurality of times.

4. The magnetic resonance imaging apparatus according to claim 3, wherein the processing circuitry is configured to calculate the weighting coefficient on a basis of the intensity of the gradient magnetic field corresponding to each of the plurality of times and a maximum value of the intensity of the gradient magnetic field.

5. The magnetic resonance imaging apparatus according to claim 1, wherein the processing circuitry is configured to calculate the weighting coefficient in such a manner that a weighting coefficient corresponding to a time during a rising time period or a falling time period of the gradient magnetic field is smaller than a weighting coefficient corresponding to a time during a time period other than time periods of ramps of the gradient magnetic field.

6. The magnetic resonance imaging apparatus according to claim 1, wherein the processing circuitry is configured to calculate the weighting coefficient on a basis of an intensity of the gradient magnetic field corresponding to each of a plurality of times and a model value for the intensity of the gradient magnetic field corresponding to each of the plurality of times.

7. The magnetic resonance imaging apparatus according to claim 6, wherein the processing circuitry is further configured to acquire data related to a waveform of the gradient magnetic field and the processing circuitry is configured to calculate the weighting coefficient on a basis of the intensity of the gradient magnetic field corresponding to each of the plurality of times obtained from the data and the model values.

8. The magnetic resonance imaging apparatus according to claim 1, wherein the processing circuitry is configured to calculate the weighting coefficient on a basis of a correspondence relationship between times and positions in a k-space, of pieces of data acquired at the times during an application of the gradient magnetic field.

9. The magnetic resonance imaging apparatus according to claim 8, wherein the processing circuitry is configured to calculate a first weighting coefficient corresponding to each of times on a basis of information about the gradient magnetic field and calculates, as the weighting coefficient, a second weighting coefficient determined with respect to each of overlapping positions in the k-space on a basis of the first weighting coefficients and the correspondence relationship.

10. A magnetic resonance imaging method executed by a magnetic resonance imaging apparatus, including:
acquiring, by sequence controlling circuitry, first k-space data in units of a plurality of segments while arranging the plurality of segments to overlap one another in a read-out direction, the first k-space being divided into the plurality of segments in the read-out direction;
calculating, by processing circuitry, a weighting coefficient on a basis of information about a gradient magnetic field related to the acquisition; and
generating, by the processing circuitry, second k-space data on a basis of the plurality of segments in the first k-space data and the weighting coefficient.
